(19) United States
(12) Patent Application Publication
(10) Pub. No.: US 2011/0101992 A1
(43) Pub. Date: May 5, 2011

(54) METHOD AND DEVICE FOR MONITORING A PIEZO ACTUATOR

(75) Inventors: Yanqi Zu, Vaihingen (DE); Stefan Schempp, Wernau (DE); Michael Danic, Stuttgart (DE); Matthias Bitzer, Gaertringen (DE)

(73) Assignee: ROBERT BOSCH GMBH, Stuttgart (DE)

(21) Appl. No.: 12/991,485

(22) PCT Filed: Mar. 30, 2009
(86) PCT No.: PCT/EP2009/053728

§ 371 Date: Jan. 21, 2011

(30) Foreign Application Priority Data
May 6, 2008 (DE) 102008001571.7

(51) Int. Cl. G01R 31/02

(52) U.S. Cl. 324/537

(57) ABSTRACT

The invention describes a device and a method for monitoring a piezoelectric actuator. It is checked whether a discharge time assumes an inadmissible value, whether the voltage at the piezoelectric actuator assumes an inadmissible value and whether a fault signal is present. A short circuit of a battery switch is detected if the three conditions are met.

### BACKGROUND INFORMATION

A method for charging and discharging a piezoelectric element is described in German Patent No. DE 197 33 560. The charging current charging the piezoelectric element and the discharging current discharging the piezoelectric element are conducted via a component having inductive properties. A piezoelectric element that is not in order is detected, in this context, if the curve over time ascertained and/or the progress in charging and/or discharging deviates from a normal curve and/or progress.

The charging switch and the associated discharging switch are important components of an appropriate device for controlling a piezoelectric element. The two switches are operated at each activation. The defects of such a switch are problematic. Particularly problematic is a fault in which the charging switch is short circuited and remains in its closed position. This fault is particularly problematic if a fault in the discharging switch occurs at the same time, and it remains in its open state. In this case, the whole buffer voltage is present at the plug of the control unit and at the piezoelectric element. Such a fault has to be safely detected in each case. In particular, this fault also has to be detected constantly in a running operation.

### SUMMARY OF THE INVENTION

The device according to the present invention and the method according to the present invention have the advantage that a fault in the piezo actuator or in its control circuit is able to be safely detected. Because three conditions are monitored, a corresponding fault is able to be safely detected and corresponding emergency measures are able to be initiated. Furthermore, because of the monitoring of three conditions, it is possible to distinguish this fault from other faults. It is particularly advantageous if it is checked whether the voltage at the piezo actuator is assuming an inadmissible value, that it is checked whether a fault signal is present, and that it is checked that the discharge time is assuming an inadmissible value.

### BRIEF DESCRIPTION OF THE DRAWINGS

FIG. 1 shows a block diagram of the important elements of a circuit for controlling a piezo actuator.

FIGS. 2 and 3 show various signals plotted over time.

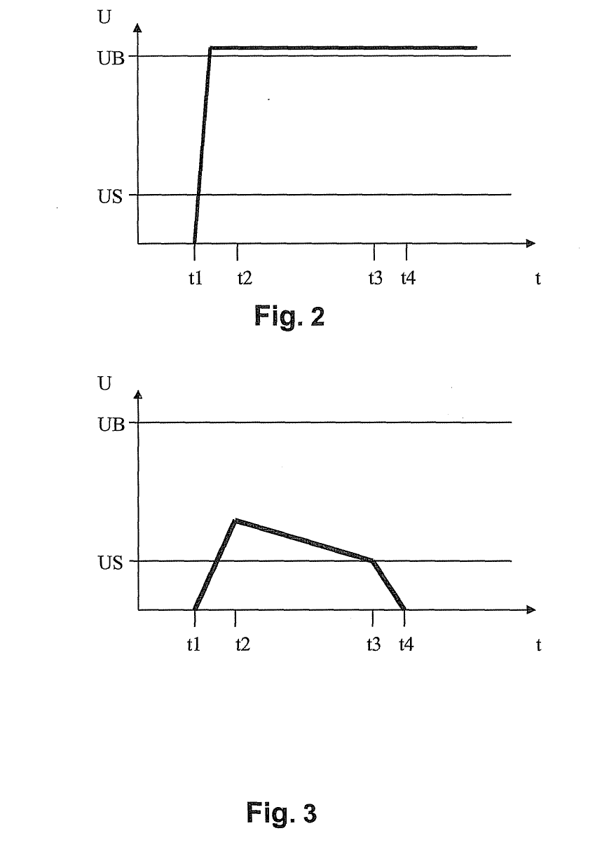

### DETAILED DESCRIPTION

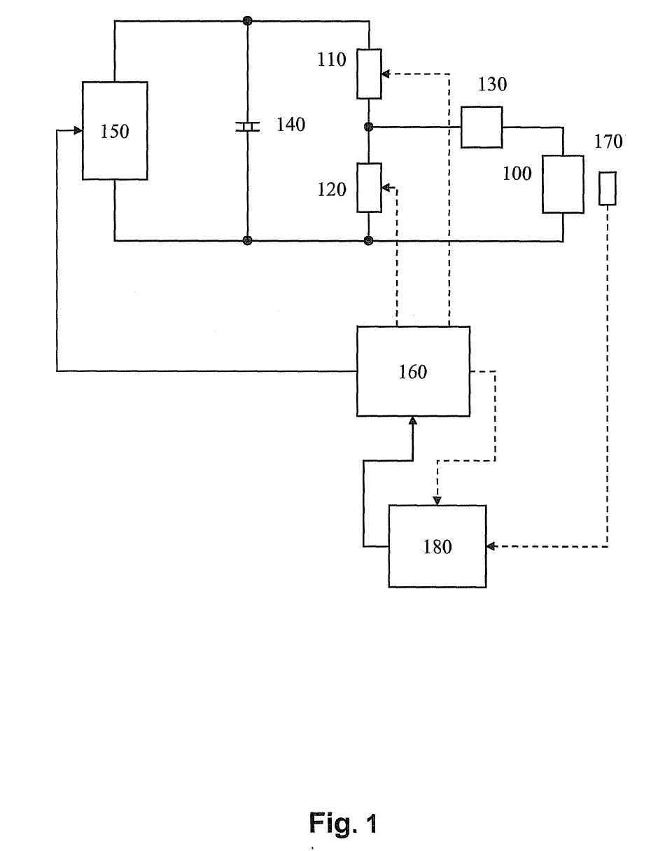

FIG. 1 shows the important elements of a circuit configuration for controlling a piezo actuator. The piezo actuator is designated by 100. The first terminal of the piezo actuator is connected, for one, to a charging switch 110 and to a discharging switch 120. The common point between charging switch 110 and discharging switch 120 is preferably connected, in this instance, via an inductance 130 to the first terminal of piezo actuator 100. The terminal of charging switch 110 facing away from the common point is connected to a first terminal of a buffer capacitor 140. The second terminal of discharging switch 120, facing away from the common point, is connected to the second terminal of buffer capacitor 140. The two terminals of buffer capacitor 140 are connected to a transformer 150. The charging switch and the discharging switch are controlled by an output stage component 160. Furthermore, a voltage recording means 170 is provided, which records the voltage that is present at piezo actuator 100. It acts on a monitoring unit 180 using an appropriate signal. Moreover, monitoring unit 180 evaluates an output signal of output stage component 160.

The circuit shown in FIG. 1 is used for controlling the piezo actuator. By an appropriate modification of the circuit, this circuit may also be used for controlling a plurality of piezo actuators. It is provided in particular that, even for a plurality of piezo actuators, only one charging switch and one discharging switch and one inductance 130 are provided. In this case, the piezo actuators that are to be controlled are selected by appropriate switching means, especially so-called selector switches.

In one embodiment it may also be provided that a plurality of piezo actuators are combined to a bank and that in each case the correspondingly shown components are provided.

This device now works as follows: Transformer 150 charges buffer capacitor 140 to a certain voltage. By controlling the charging switch, piezo actuator 100 is charged to a specified voltage. When the voltage at piezo actuator 100 reaches the specified voltage, the charging process is ended and the charging switch usually remains in its open state. If the piezo actuator is to be discharged, the discharging switch is activated accordingly and the piezo actuator is also discharged via inductance 130 and discharging switch 120. For this purpose, the charging and discharging switches, as well as the additional switches (not shown) such as selector switches, are activated by output stage component 160.

The voltage curve of a fault-free operation is shown in exemplary fashion in FIG. 3. At time T1 the charging process of the piezo actuator begins. At time T2 the voltage at the piezo actuator reaches a specified value. The charging process ends at this time. Usually the time duration between time T1 and time T2 is designated as the charging time. By time T3 the voltage at the piezo actuator has dropped to the value US. The activation of the piezo actuator ends at time T3 and by the operation of discharging switch 120, the voltage drops to zero by time T4. The time duration between time T3 and time T4 is usually designated as discharge time.

Now, if a short circuit occurs in the charging switch, the voltage rises substantially faster and to a higher value, during the charging process. In particular, the voltage at the piezo actuator rises to the value of the voltage at buffer capacitor UB. When this voltage is reached, the voltage at the piezo actuator remains at this value. Discharging at time T3 is no longer possible, in particular in the case of an additional defect of the discharging switch, which remains in an open position.

The result is that a discharge time can no longer be measured, or rather, assumes a very large value. Moreover, the recorded voltage at time T2 is substantially greater than the usual value.

Now, according to the present invention, it is provided that essentially three variables are evaluated. For one, it is checked whether the discharge time, which preferably via a signal provided by output stage component 160, which is measured by monitoring unit 180, corresponds to the time between the beginning of the discharge process and the end of the discharge process, at which the voltage at the piezo actuator reaches its switch-off value. This value of the discharge time is usually set to a fixed value by the output stage component, said fixed value being then output by the output stage component when the discharge time cannot be measured. For the purpose of fault monitoring, in monitoring unit 180 the discharge time is compared to a threshold value. Furthermore, the voltage present at the piezo actuator, is compared to a specified value, preferably at time T2. This specified value is in the range above the usual setpoint switch-off voltage. If this value is substantially greater than this specified value, the presence of a second condition is detected.

Usually it is provided that output stage component 160 carry out a diagnosis of the device. To do this, it is provided that various voltage and current values are recorded, and, in response to an implausibility, a fault in the system is detected. In this case, an error bit is set. As a third condition it is checked whether this error bit has been set.

If all these conditions exist, a fault is detected that indicates that the charging switch has remained in its closed state, or rather, that there is a short circuit in the charging switch. A mix-up with other defects is excluded because three conditions are checked. If such a fault is detected, transformer 150 is controlled by monitoring unit 180 via the output stage component in such a way that additional charging of buffer capacitor 140 is omitted, and when such a fault exists, the buffer capacitor is discharged. By using this measure, a safe operating state of the device is achieved.

In the case of control devices in which two transformers and two buffer capacitors as well as two output stage components are provided, in this case an emergency operation is additionally necessary to the extent that only that transformer is switched off which controls the charging switch that has been detected as being defective. In this case, emergency operation using a reduced number of cylinders of the internal combustion engine is possible.

1-6. (canceled)

7. A method for monitoring a piezo actuator, comprising:
checking whether a discharge time is assuming an inadmissible value;
checking whether a voltage at the piezo actuator is assuming an inadmissible value;
checking whether there is a fault signal present; and
detecting a short circuit of a charging switch when the three conditions are met.

8. The method according to claim 7, wherein it is checked whether the discharge time is greater than a threshold value.

9. The method according to claim 7, wherein it is checked whether the voltage at a certain time is greater than a threshold value.

10. The method according to claim 7, wherein at a time at which a charging process of the piezo actuator is ended, in a fault-free case, it is checked whether the voltage is greater than a threshold value.

11. The method according to claim 7, wherein it is checked whether an output stage component is outputting a fault signal.

12. A device for monitoring a piezo actuator, comprising:
means for checking whether a discharge time is assuming an inadmissible value;
means for checking whether a voltage at the piezo actuator is assuming an inadmissible value;
means for checking whether there is a fault signal present; and
means for detecting a short circuit of a charging switch when the three conditions are met.
